(19) United States
(12) Patent Application Publication
(10) Pub. No.: US 2009/0174054 A1
(43) Pub. Date: Jul. 9, 2009

(54) Module with Flat Construction and Method for Placing Components

(76) Inventors: Christian Block, Stainz (AT); Sebastian Brunner, Graz (AT); Christian Hoffmann, Deutschlandsberg (AT)

Correspondence Address: SLATER & MATSIL, L.L.P., 17950 PRESTON RD, SUITE 1000, DALLAS, TX, 75252-5793, US

(21) Appl. No.: 12/352,436

(22) Filed: Jan. 12, 2009

Related U.S. Application Data
(63) Continuation of application No. PCT/DE2007/001155, filed on Jun. 29, 2007.

(30) Foreign Application Priority Data
Jul. 18, 2006 (DE) 10 2006 033 222.9

(51) Int. Cl. H01L 23/488; H01L 21/60

(52) U.S. Cl. 257/690; 438/106; 257/E23.023; 257/E21.508

(57) ABSTRACT

A module for electrical components is proposed in which connection surfaces that can be bonded are provided on a multi-layer substrate with integrated wiring; a component chip is bonded on the top that has bond pads on its surface pointing upward and that contacts the substrate by means of bonding wires. Here, the wire guide of the bonding wires is so that they are each bonded with a ball on a connection surface and with the wedge directly on one of the bond pads.

This application is a continuation of co-pending International Application No. PCT/DE2007/001155, filed Jun. 29, 2007, which designated the United States and was not published in English, and which claims priority to German Application No. 10 2006 033 222.9 filed Jul. 18, 2006, both of which applications are incorporated herein by reference.

### BACKGROUND

Modules are used for integrating different components on a substrate. Typically, components are connected to each other by means of the modules. One encapsulation of the entire module can here replace the encapsulation of individual components.

The reliability of modules under loading caused by temperature changes essentially depends on the construction and connection technique and also on the encapsulation of the module. For modules in which component chips are connected to the module substrate by means of bonding wires, the bonding wires represent particular weak points, because they tend to tear under tensile stress caused, e.g., by different thermal expansion, wherein the function of the entire module is disturbed or destroyed.

One method of wire bonding is the so-called stand-off stitch bonding (SSB) in which initially a so-called stud bump is generated on a second bond pad. A stud bump is the end of a bonding wire formed into a ball by fusion bonded onto the bond pad and in which immediately after the bonding, the wire is torn away above the ball. In the second processing step, a conventional ball stitch is constructed, wherein the bonding wire is bonded by means of its end formed into a ball on a first bond pad and the other end of the bonding wire designated as a wedge or stitch is placed directly on the stud bump on the second bond pad. In the so-called “reverse ball stitch” method, a stud bump is mounted on the component chip, and the ball is mounted on the substrate. The stud bump is used in the “reverse ball stitch” bonding to bond the wedge at a distance from the second bond pad to protect against damage to the chip surface due to the wire-guiding capillary of the bonding robot, in particular, when the bonding wire is pinched at the end.

It has been found that the thermal stability of modules with wire-bonded component chips is essentially dependent on the length of the bonding wires and, in particular, on the height of the loops that the bonding wires form fixed at both ends, in particular, when the bonding wires are still covered with a glob top or mold.

### SUMMARY

In one aspect, the present invention specifies a module with wire-bonded component chips, wherein this module is more resistant to changes in thermal stress.

In one embodiment, a module is specified that has a bonded component chip contacting the module substrate by means of bonding wires. For reducing the total component height, the already described “reverse ball stitch” method is used, wherein, however, the wire end of the bonding wire already bonded on the module substrate is bonded directly onto the bond pad of the component chip without an intermediate stud bump. In this way, it is possible to guide the bonding wire flat across the surface of the component chip without having to take into account a large wire loop projecting past the component chip. On the substrate, the bonding wire is conventionally bonded to a ball on the connection surfaces provided there.

The bonding wire can have a round or also a rectangular cross-sectional area. In the extreme case, it is constructed as a metal ribbon. This construction can be guided in an especially flat way and has advantages if HF (high frequency) signals are to be guided via the bonding wire or the metal ribbon. Due to the skin effect, HF signals have only a minimal “immersion depth” into the metal ribbon. A rectangular bonding wire allows a smaller overall height relative to a round bonding wire for the same size cross-sectional area. A metal ribbon used as a bonding wire can be bonded on both ends as a wedge (stitch) and requires no ball as a first bond.

Such a module can be covered with a glob top mass or a mold mass that is deposited through injection molding and that can be deposited in a lower total height than before due to the lower loop height of the bonding wires. This increases the stability of the proposed module such that by means of the more unstable of the two bonding connections of a bonding wire, namely by means of the wedge bonding connection, now only a small glob top thickness is to be deposited across the surface of the component chip pointing upward. The tensile and shear forces that act in the module due to the different coefficients of thermal expansion are a function of the glob top thickness deposited above the corresponding susceptible position, here the bonding wire connection. Thus, both the bond connection with smaller load capacity is better protected and due to the overall lower glob top height, the stability of the more stable bonding wire connection is also increased directly on the substrate. A lower glob top cover also leads to a lower module height.

For further improvement of the strength of the wedge-bonded bonding wire end, a stud bump can be deposited above the wedge bond. This stud bump sits on the bonding wire end and on the bond pad and represents an additional attachment of the bonding wire end that makes this bond connection more stable against tearing of the bonding wire or detachment of the bond connection.

For wedge or stitch bonding, the bonding device, that is, the wire-guiding capillary, must act on the bond pad with relatively high pressure. Here, to avoid damage to the chip passivation deposited on the surface of the component chip pointing upward, the bond pad can be constructed in a special way according to an embodiment of the invention. While up until now, first the bond pad and then the passivation were generated, which led to a partial overlap of the passivation above the bond pad, now the bond pad is constructed so that it extends across the passivation on all sides, and this cannot be damaged by the wire-guiding capillary.

Therefore it is proposed for the bond pad to initially deposit a ground metallization on the component chip, then to generate a passivation, if necessary, and then to deposit on the ground metallization a reinforcement layer that creates a surface that can be bonded. The reinforcement layer is here deposited so that the joint between the passivation layer and the ground metallization is covered. Advantageously, the surface of the ground metallization initially covered by the passivation layer is exposed in a structured window in the passivation layer. In addition, the reinforcement layer is deposited so that it assumes a larger surface area than the window and therefore overlaps the edges of the passivation layer.

Further reduction of the total module height and, in particular, the required glob top height is achieved when the height of the component sitting on the substrate and especially of the component chip is minimized. In addition to the lower module height, the stability is also improved due to the lower glob top thickness.

The lower component chip height has an advantageous effect on the module height only when no SMD (surface mounted device) components are mounted on the substrate. Even if additional SMD components are mounted, with the advantageously proposed wire bonding, a gain in stability is achieved that is independent of the deposited glob top thickness.

Resistors can be integrated into the module. Because these often cannot be generated within the multi-layer substrate, for this purpose, for example, SMD resistors can be used. It is possible, however, and for a small module height also required, to replace SMD resistors by printed resistors deposited directly on the substrate surface. For example, a resistive paste can be printed before the sintering of the substrate as an inner layer print, or after the sintering as an outer layer print, and can be covered with a passivation layer, in particular, with a glass layer both against corrosion and also against galvanic intensification or galvanic damage/decomposition. Such an exposed resistive layer has the additional advantage that it can be trimmed at a later time, for example, by means of a laser.

One advantageous substrate material is a multi-layer ceramic, in particular, an LTCC (Low Temperature Cofired Ceramic) that comprises several dielectric ceramic layers between which structured metallization layers are provided. Different metallization layers are connected via contacts. An arbitrary connection pattern in the substrate can be integrated by means of the metallization structures within the metallization layers and their connection via contacts.

It is also possible to realize passive components defined in this way, for example, resistors, capacitors, and inductors. Therefore, in this way, simple circuits can also be generated directly in the substrate, for example, matching circuits.

For placing components of a substrate for a module in the proposed construction with low structural height, initially a substrate with connection surfaces that can be bonded and a component chip with bond pads on its front side are provided. The bond pads are constructed so that the surface that can be bonded projects across the surface of the passivation and advantageously partially overlaps the passivation.

In the first step, the component chip is bonded on the provided space on the substrate. Here, it is possible to produce an electrical reverse side connection of the chip simultaneously by means of a corresponding “die flag” on the substrate. It is also possible, however, to bond the chip purely mechanically and to electrically contact it exclusively by bonding wires. For this purpose, a bonding wire is bonded with the “ball” on the connection surfaces on the substrate. Then the bonding wire is bent to a flat loop, so that it runs close to the surface of the component chip up to the bond pad. Now the wedge (or stitch) is set directly on the surface of the bond pad on the surface of the component chip pointing outward in which the wire end of the bonding wire is placed and bonded oriented flat or parallel to the bond pad.

The bonding method can comprise an ultrasound-supported thermal compression method or a so-called friction welding method in which the contact force, temperature, and ultrasound energy can interact and create the bond connection. The bond pad projecting across the passivation on the surface of the chip pointing upward contributes to the fact that during the bonding method, there is no direct effect of the bonding tool—a wire-guiding capillary—on the passivation on the component chip. Therefore, damage to the passivation is prevented.

Through the bonding, the wire is torn behind the wedge or pinched by the capillary. Then, selectively, by the wedge bond connection, a stud bump is set while the end of another bonding wire is fused into a ball and placed on the bonding point. After the bonding, the projecting wire is torn, wherein only the stud bump remains that contacts the end of the wedge-bonded bonding wire and the underlying bond pad and thus increases the strength of the wedge bond connection.

A number of wire bonding connections corresponding to the number of contacts to be produced is generated according to the method just described. Then, additional, optionally different component chips can be deposited on the substrate using the same or flip-chip technology, as well as, optionally SMD components. It can be useful to create the bonding wire connections for all chips to be bonded in this way on a substrate in a common processing step.

For protecting the deposited components and, in particular, their bonding wire connections, these are then covered under a glob top mass or mold mass. The bonding wires and the components are thus protected from mechanical damage and from corrosion.

### BRIEF DESCRIPTION OF THE DRAWINGS

Below, the invention will be explained in greater detail with reference to embodiments and the associated figures. The figures are constructed only schematically and are not true to scale, so that neither absolute nor relative dimensional information is to be taken from the figures. Parts that are identical or that act identically are designated with identical reference symbols.

FIG. 1 shows, in a schematic cross section, conventional wire bond connections on a module;

FIG. 2 shows a module with wire bond connections according to the invention in a schematic cross section;

FIGS. 3A and 3B show the production of the new bond connection in comparison with a known ball stitch method; and

FIG. 4 shows a wedge mounted with an additional stud bump.

### DETAILED DESCRIPTION

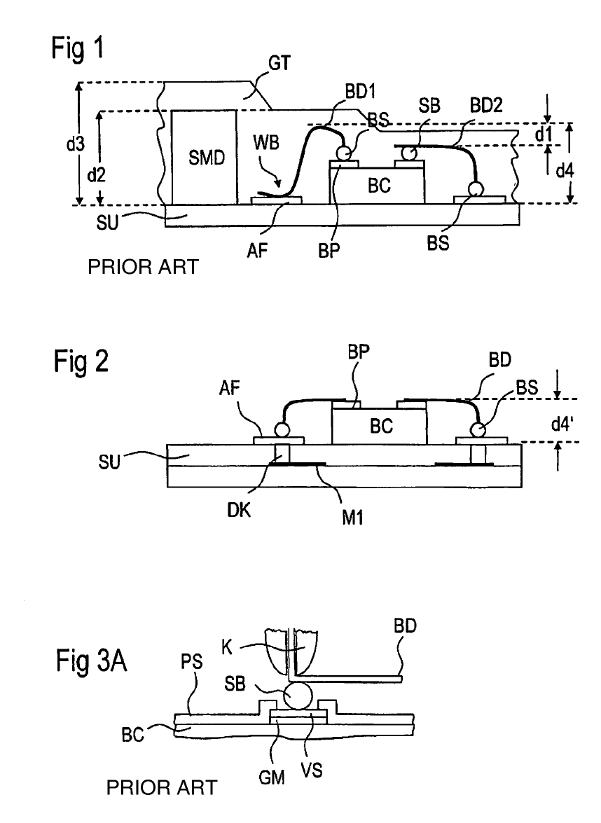

In the schematic cross section, FIG. 1 shows an example module with a bonded component chip BC connected to the substrate SU by means of conventional and therefore known bonding wire connections. On the substrate are connection surfaces AF that can be bonded and on the reverse side of the component chip BC are bond pads BP that can be bonded. In the figure, both a standard ball stitch bonding connection according to the left bonding wire BD1 and also a reverse stand off stitch (reverse SSB) bond connection according to the second bonding wire BD2 on the right side are shown. In the conventional ball stitch bond connection, the bonding wire end BS fused into a ball is first set on the component chip or its bond pad and then drawn toward the connection surface AF on the substrate SU, where a wedge bond WB is produced. In the reverse sequence, for the reverse SSB initially a stud bump SB is placed on the bond pad BP, and the bonding wire is torn above the ball generated there, wherein the stud bump remains. Then a bonding wire end is bonded with the ball BS on the connection surface AF, and the bonding wire BD2 is then drawn toward the stud bump SB, and a wedge bond connection is created there.

It has been shown that the reverse SSB technique leads to a structural height of the module reduced by the distance dl when the uppermost loop of a bonding wire determines the structural height. The savings (corresponding to dl) obtained in this way can equal 50 to 100 μm for common components or common bonding wire loops. In addition, SMD components SMD can be arranged on the substrate SU. These typically have a component height that exceeds that of a component chip. While a component chip mounted as a bare die can be realized in a standard thickness of, for example, 200 μm, an SMD component requires a component height of typically 500 μm. For protection, the module is still provided with a glob top cover GT that is deposited in a thick construction so that the bonding wires BD1 and BD2 are reliably covered. This leads to a component height of at least d2, in the case of the use of SMD components to a component height d3, wherein d3 is greater than d2.

In contrast, FIG. 2 shows a component chip BC contacted according to an embodiment of the invention. Here, the component chip BC is also bonded on the substrate SU. A bonding wire BD is bonded with its ball BS on the connection surface AF directly on the substrate. The bonding wire is now drawn on the top side toward the bond pads BP and there bonded with a wedge connection WB directly on the bond pad BP. It has been shown that the bonding wire can be guided in this way close to the component chip BC and leads to only a small projection above the component chip height. The total height of the component d4′ measured from the substrate up to the highest bonding wire loop is only insignificantly higher than the thickness of the component chip BC.

Furthermore, multi-layer wiring is indicated in FIG. 2 in a multi-layer substrate SU. Here, the connection surfaces AF can be connected via contacts DK to a metallization layer M1 buried in the interior of the substrate. This can be connected to other metallization layers via contacts, wherein metallization structures for creating wiring or for realizing passive component structures are arranged in each metallization layer. External contacts of the module can be arranged on the bottom side of the substrate SU.

In the known construction according to FIG. 1 and the construction according to an embodiment of the invention from FIG. 2, component chips of identical component height are used, so with the construction according to an embodiment of the invention, a height-reduced component is produced that can also be realized for a glob top cover with a smaller thickness of the glob top cover. On the interface to the component chip BC or to the substrate SU, a thinner glob top cover leads to smaller shear forces that thus load the bond connections and the chip less for changes in temperature loading acting on the module.

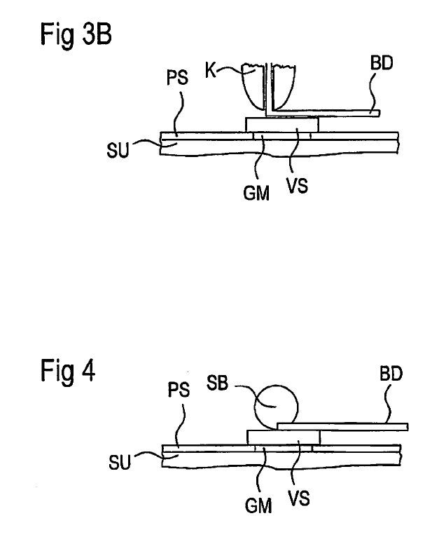

FIGS. 3A and 3B compare a known bond pad on the chip top side of a component chip BC with a construction of a bond pad that is advantageous for the new bonding method. FIG. 3A shows the known bond pad during the production of a bonding wire connection according to the reverse SSB method. The bond pad has a ground metallization GM and above this reinforcement layer VS that is distinguished by its bonding ability, for example, a gold surface.

After the production of the bond pad, a passivation layer PS is deposited on the chip surface and is structured so that a region of the bond pad is exposed. Therefore, the edges of the passivation layer typically overlap the bond pad. In the reverse SSB method, therefore, a stud bump SB on which a wedge can then be placed in the reverse SSB method is initially bonded as a spacer, as already described. Here, the bonding tool, of which only the capillary K leading to the bonding wire is shown, presses the bonding wire BD onto the stud bump SB, bonds it there fixed, and then tears or pinches it.

FIG. 3B shows a new construction of the bond pad in which, initially, a ground metallization for the bond pad is generated on the substrate surface SU. Then the passivation is generated and optionally structured. Only after the production of the passivation PS is a reinforcement layer VS deposited above the bond pad, for example, through galvanic growth of a corresponding metal layer. This leads to the fact that the edges of the reinforcement layer grow past the edges of the passivation layer and finally can even overlap it. Overall, the reinforcement layer is deposited in such a height that it projects above the top edge of the passivation layer. This projection replaces the stud bump of the conventional reverse SSB method. Such a bond pad surface raised above the surface of the passivation layer allows a problem-free direct wedge bonding of a bonding wire end in the reverse ball stitch method on the surface of the reinforcement layer, without damaging the passivation layer PS with the capillary K.

In a schematic cross section, FIG. 4 shows how such a wedge-bonded wire end is also still attached to a stud bump SB bonded on the bond pad BP directly above the torn wire end.

The invention shown and explained only with reference to a few embodiments is not limited to the embodiments. Possible variants result, especially in the type and number of components to be deposited on the substrate and those already deposited, for example, as bare dies. These can represent ICs (integrated circuits) or other active semiconductor components. The bare die can also be a piezoelectric chip. The component chip can have component structures on both surfaces and also within the chip. On the side to be bonded, it can have a ground metallization or a ground contact. A module according to an embodiment of the invention with minimized module height eliminates SMD components.

However, the invention is not limited to modules without SMD components. The components and component chips arranged on the substrate can have different structural heights. Accordingly, the glob top cover can also have a stepped construction so that all of the components are covered flush by the glob top or a mold (by means of injection molding).

The invention is also not limited to substrates made from LTCC. Also possible are polymer substrates that have, however, relative to the LTCC, a thermal expansion behavior that is matched more poorly with the expansion behavior of typical component chips and, in particular, semiconductors. A module according to the invention can also be realized without a glob top cover, wherein, for protecting the bonding wire connections, however, a different type of cover is required, for example, a cap or the like.

What is claimed is:

1. A module for electrical components, the module comprising:
a multi-layer substrate, including wiring integrated with the substrate and connection areas at a top surface of the substrate;
a component chip bonded to the top surface of the substrate, the component chip having bond pads at a surface pointing upward;
bond wires connecting the bond pads of the component chip to respective connection areas of the substrate, wherein the bond wires are each bonded with a ball on a connection area and with a wedge directly on one of the bond pads.

2. The module according to claim 1, wherein the bond wires are formed as flat loops following the surface of the component chip.

3. The module according to claim 2, further comprising a glob top covering the top surface of the substrate up to and past the height of the loops of the bond wires.

4. The module according to claim 1, wherein a stitch is bonded on a wedge-bonded wire end and the bond pad.

5. The module according to claim 1, wherein each bond pad comprises:
a ground metallization over the component chip;
a passivation layer, wherein the component chip and lateral edges of the bond pads are covered with the passivation layer; and
a reinforcement layer over the ground metallization and covering a joint between the passivation layer and ground metallization.

6. The module according to claim 5, wherein the reinforcement layer projects past the passivation layer in a direction away from the component chip.

7. The module according to claim 5, wherein the reinforcement layer overlaps lateral edges of the passivation layer.

8. The module according to claim 1, wherein the component chip has a thickness not greater than 200 μm.

9. The module according to claim 5, wherein the reinforcement layer comprises a Cu layer and an Au layer.

10. The module according to claim 1, further comprising a resistor on the substrate, the resistor comprising a printed strip conductor made from a resistive paste.

11. The module according to claim 1, wherein the substrate comprises an FR4 material.

12. The module according to claim 1, wherein the substrate comprises an LTTC ceramic.

13. The module according to claim 1, wherein the bond wires comprise metallic ribbons.

14. A method for assembling a module, the method comprising:
providing a substrate with connection surfaces and a component chip with bond pads;
attaching the component chip to the substrate;
bonding a bonding wire with a ball on one of the connection surfaces; and
bonding an opposite end of the bonding wire with a wedge directly on the bond pad.

15. The method according to claim 14, further comprising bonding a stud bump above the bonded wedge.

16. The method according to claim 14, wherein the bonding wire is shaped into a flat loop that follows a surface of the component chip while located above the surface and is first bent downward toward the substrate next to the component chip.

17. The method according to claim 14, further comprising depositing a glob top mass or mold mass up to a height such that the bonding wire is completely covered.

18. The method according to claim 14, wherein each bond pad comprises:
a ground metallization over the component chip;
a passivation layer, wherein the component chip and lateral edges of the bond pads are covered with the passivation layer; and
a reinforcement layer over the ground metallization and covering a joint between the passivation layer and ground metallization.
